(19) United States
(12) Patent Application Publication
(10) Pub. No.: US 2016/0260914 A1
(43) Pub. Date: Sep. 8, 2016

(54) LIGHT-EMITTING MATERIAL AND ORGANIC LIGHT-EMITTING DEVICE

(71) Applicants: Cambridge Display Technology Limited, Godmanchester (GB); Sumitomo Chemical Company Limited, Tokyo (JP)

(72) Inventors: Kiran Kamtekar, Godmanchester (GB); William Tarran, Godmanchester (GB); Tania Zuberi, Godmanchester (GB)

(73) Assignees: Cambridge Display Technology Limited, Godmanchester (GB); Sumitomo Chemical Company Limited, Tokyo (JP)

(21) Appl. No.: 15/059,812

(22) Filed: Mar. 3, 2016

(30) Foreign Application Priority Data
Mar. 4, 2015 (GB) 1503667.6

(51) Int. Cl. H01L 51/00; C09K 11/02; C07F 15/00; C09K 11/06

(52) U.S. Cl. CPC H01L 51/0085; C09K 11/06; C09K 11/025; C07F 15/0033; C09K 2211/185; H01L 51/504

(57) ABSTRACT

A compound of formula (I)

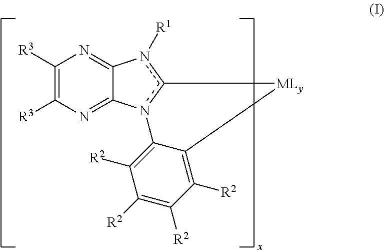

wherein M is a transition metal; L is a ligand; x is at least 1; y is 0 or a positive integer; R¹ in each occurrence is independently a substituent; R² and R³ in each occurrence is independently H or a substituent, with the proviso that at least one of R¹, R² and R³ is a group X comprising at least one aryl or heteroaryl group. The compound of formula (I) may be used as a phosphorescent material in an organic light-emitting device.

### RELATED APPLICATIONS

This application claims the benefits under 35 U.S.C. §119(a)-(d) or 35 U.S.C. §365(b) of British application number GB 1503667.6, filed Mar. 4, 2015, the entirety of which is incorporated herein.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton).

Phosphorescent dopants are also known (that is, a light-emitting dopant in which light is emitted via decay of a triplet exciton).

US 2012/228583 discloses compounds having the formula:

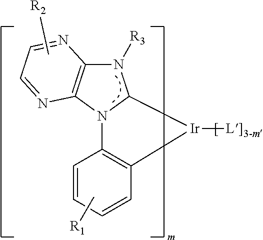

### SUMMARY OF THE INVENTION

In a first aspect the invention provides a compound of formula (I)

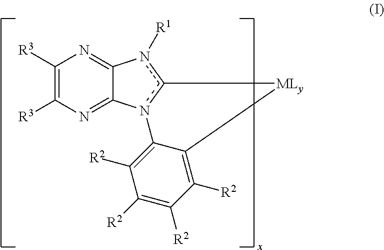

wherein:

M is a transition metal;

L is a ligand;

x is at least 1;

y is 0 or a positive integer;

R¹ in each occurrence is independently a substituent;

R² in each occurrence is independently H or a substituent; and

R³ in each occurrence is independently H or a substituent,

with the proviso that at least one of R¹, R² and R³ is a group X comprising at least one aryl or heteroaryl group.

In a second aspect the invention provides a composition comprising a host material and a compound according to the first aspect.

In a third aspect the invention provides a formulation comprising a solvent and a compound according to the first aspect or a composition according to the second aspect dissolved in the solvent.

In a fourth aspect the invention provides an organic light-emitting device comprising an anode, a cathode and a light-emitting layer between the anode and cathode wherein the light-emitting layer comprises a compound according to the first aspect or a composition according to the second aspect.

In a fifth aspect the invention provides a method of forming an organic light-emitting device according to the fourth aspect comprising the steps of forming the light-emitting layer over the anode; and forming the cathode over the light-emitting layer.

“Aryl” as used herein means a monocyclic or polycyclic aromatic group.

“Heteroaryl” as used herein means a monocyclic or polycyclic heteroaromatic group.

### DESCRIPTION OF THE DRAWINGS

The invention will now be described in more detail with reference to the drawings in which:

FIG. 1 illustrates schematically an OLED according to an embodiment of the invention.

### DETAILED DESCRIPTION OF THE INVENTION

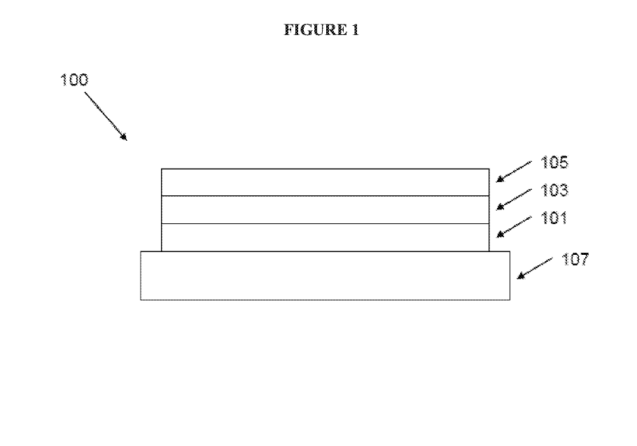

FIG. 1, which is not drawn to any scale, illustrates an OLED 100 according to an embodiment of the invention supported on a substrate 107, for example a glass or plastic substrate. The OLED 100 comprises an anode 101, a light-emitting layer 103 and a cathode 105.

Light-emitting layer 103 comprises a phosphorescent light-emitting material of formula (I) and may comprise one or more further light-emitting materials. Preferably, light-emitting layer 103 comprises at least one further light-emitting material that produces light during operation of the device 100. Preferably, any further light-emitting material of the light-emitting layer 103 is a phosphorescent material.

The or each phosphorescent material of the light-emitting layer 105 may be doped in a host material. The lowest excited state triplet energy (T₁) level of the host material is preferably no more than 0.1 eV below that of the compound of formula (I), and is more preferably about the same or higher than that of the compound of formula (I) in order to avoid quenching of phosphorescence.

One or more further layers may be provided between the anode 103 and cathode 105, for example hole-transporting layers, electron transporting layers, hole blocking layers and electron blocking layers. The device may contain more than one light-emitting layer.

Preferred device structures include:

Anode/Hole-injection layer/Light-emitting layer/Cathode

Anode/Hole transporting layer/Light-emitting layer/Cathode

Anode/Hole-injection layer/Hole-transporting layer/Light-emitting layer/Cathode

Anode/Hole-injection layer/Hole-transporting layer/Light-emitting layer/Electron-transporting layer/Cathode.

Preferably, at least one of a hole-transporting layer and a hole injection layer is present. Preferably, both a hole injection layer and a hole-transporting layer are present.

If present, a charge-transporting layer adjacent to light-emitting layer 105 preferably contains a charge-transporting material having a T₁ excited state energy level that is no more than 0.1 eV lower than, preferably the same as or higher than, the T₁ excited state energy level of the compound of formula (I) in order to avoid quenching of triplet excitons migrating from the light-emitting layer into the charge-transporting layer.

Triplet energy levels of a host material may be measured from the energy onset (energy at half of the peak intensity on the high energy side) of the phosphorescence spectrum measured by low temperature phosphorescence spectroscopy (Y. V. Romaovskii et al, Physical Review Letters, 2000, 85 (5), p 1027, A. van Dijken et al, Journal of the American Chemical Society, 2004, 126, p 7718).

The triplet energy level of a phosphorescent material may be measured from its photoluminescence spectrum.

Preferably, substantially all light emitted by the device is phosphorescence.

In one embodiment substantially all light emitted during operation of the device 100 is emitted from light-emitting materials in light-emitting layer 105.

In other embodiments, two or more layers of the device may emit light during operation of the device. Optionally, one or more charge-transporting layers may comprise a light-emitting dopant such that the charge-transporting layer(s) emit light during operation of the device.

In a preferred embodiment, the device 100 comprises a hole-transporting layer between the anode 101 and the light-emitting layer 103 wherein the hole-transporting layer comprises a light-emitting material, optionally a phosphorescent light-emitting material, such that the hole-transporting layer emits light during operation of the device.

Preferably, the compound of formula (I) is a blue phosphorescent material.

The OLED 100 may be a white-emitting OLED wherein light-emitting layer 103 alone emits white light or wherein emission from light-emitting layer 105 and another emitting layer combine to produce white light. White light may be produced from a combination of red, green and blue light-emitting materials.

White-emitting OLEDs as described herein may have a CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-6000K.

In one arrangement, light-emitting layer 103 contains red, green and blue phosphorescent materials that in operation produce white light.

In another arrangement, light-emitting layer 103 contains a blue phosphorescent compound of formula (I) and a green phosphorescent compound, and a hole-transporting layer contains a red phosphorescent compound.

A red light-emitting material may have a photoluminescence spectrum with a peak in the range of about more than 550 up to about 700 nm, optionally in the range of about more than 560 nm or more than 580 nm up to about 630 nm or 650 nm.

A green light-emitting material may have a photoluminescence spectrum with a peak in the range of about more than 490 nm up to about 560 nm, optionally from about 500 nm, 510 nm or 520 nm up to about 560 nm.

A blue light-emitting material may have a photoluminescence spectrum with a peak in the range of up to about 490 nm, optionally about 450-490 nm.

Preferably, the light-emitting material of hole-transporting layer 105, if present, is a red light-emitting material.

The photoluminescence spectrum of a material may be measured by casting 5 wt % of the material in a PMMA film onto a quartz substrate to achieve transmittance values of 0.3-0.4 and measuring in a nitrogen environment using apparatus C9920-02 supplied by Hamamatsu.

Compounds of Formula (I)

R¹ is preferably selected from the group consisting of C₁₋₂₀ alkyl and a group X comprising at least one aryl or heteroaryl group.

Optionally, R² and R³ are each independently selected from the group consisting of:

H;

D;

F;

CN;

C₁₋₂₀ alkyl, wherein one or more non-adjacent C atoms may be replaced with optionally substituted aryl or heteroaryl (preferably phenyl), O, S, C═O or —COO—, and one or more H atoms may be replaced with F;

an aryl or heteroaryl group Ar¹ that may be unsubstituted or substituted with one or more substituents selected from C₁₋₂₀ alkyl wherein one or more non-adjacent C atoms may be replaced with O, S, C═O or —COO—, and one or more H atoms may be replaced with F; and a group X comprising at least one aryl or heteroaryl group.

At least one of R¹, R² and R³ is a group X.

Preferably, R² and R³ are each independently H or X. Preferably, at least one of R² and R³ is X.

One or more R² groups may be X. In this case, preferably only one R² group is X, the remaining R² groups being H or a substituent other than X. In the case where one or more R² groups are X, R² para to M is preferably X.

One or both R³ groups may be X. In this case, preferably, only one R³ group is X, the remaining R³ groups being H or a substituent other than X.

Optionally, only one R² group and/or only one R³ group is X, the remaining R² and R³ groups independently being selected from H or a substituent other than X, preferably H.

Optionally, R¹ is a group X and at least one group selected from R² and R³, preferably only one group R² and/or only one group R³, is a group X.

If the compound of formula (I) comprises more than one group X then X in each occurrence may be the same or different.

In one preferred embodiment, X is a group of formula (II):

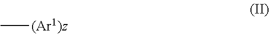

wherein Ar¹ independently in each occurrence is an aryl or heteroaryl group that may be unsubstituted or substituted; z is at least 1; and —(Ar¹)z forms a branched or linear chain of aryl or heteroaryl groups.

Optionally, substituents of Ar¹ of formula (II), where present, may be selected from C₁₋₂₀ alkyl wherein one or more non-adjacent C atoms may be replaced with O, S, C═O or —COO—, and one or more H atoms may be replaced with F.

“Branched chain of aryl or heteroaryl groups” as used herein means that at least one group Ar¹ is either directly bound to a ligand of formula (I) and to at least two further groups Ar¹, or is bound directly to at least three further groups Ar¹.

“Linear chain of aryl or heteroaryl groups” as used herein means that each Ar¹ group is either an Ar¹ group that is bound directly to a ligand of formula (I) and directly to only other Ar¹ group, or is not bound directly to a ligand of formula (I) and is bound directly to only one or two other Ar¹ groups.

Preferred aryl groups Ar^{l} are C₆₋₂₀ aryl groups, more preferably phenyl. If R¹ is X then it is preferably a group of formula (II) in which the or each Ar¹ group is a C₆₋₂₀ aryl groups, more preferably phenyl.

Preferred heteroaryl groups Ar¹ are 6-20 membered heteroaryl groups.

Optionally, X is a charge-transporting group. Preferably, a group R² or R³ that is X is preferably a charge-transporting group.

Optionally, z is an integer from 1-10.

Optionally, z is at least 2.

X may be selected from formulae (IIa)-(IIc):

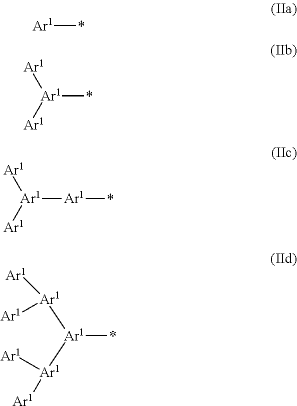

wherein * is a point of attachment to a ligand of formula (I).

Optionally, X is a charge-transporting group wherein at least one Ar¹ group is a 6-20 membered heteroaryl group. Optionally, at least one Ar¹ group is a 6-20 membered heteroaryl group of C and N atoms.

Optionally, some or all of the Ar¹ groups of formula (II) form a group of formula (IIe) or (IIf):

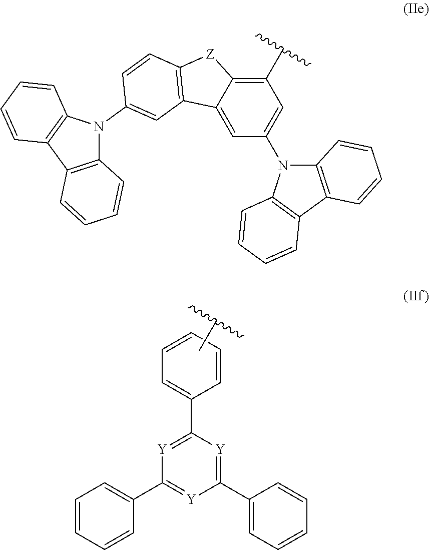

wherein each Y is C or N with the proviso that at least one X is N; Z is O, S, NR⁶, SiR⁶₂ or CR⁶₂, wherein R⁶ independently in each occurrence is a substituent, preferably a C₁₋₃₀ hydrocarbyl group, more preferably C₁₋₂₀ alkyl, unsubstituted phenyl or phenyl substituted with one or more C₁₋₁₀ alkyl groups; and

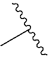

represents a bond to a ligand of formula (I) or to a further group Ar¹.

The groups of formulae (IIe) and (IIf) may be unsubstituted or may be substituted with one or more substituents, optionally one or more C₁₋₂₀ alkyl groups. If only some of the groups Ar¹ form a group of formula (IIc) or (IIf) then remaining Ar¹ groups are preferably unsubstituted or substituted phenyl, wherein the or each substituent is optionally a C₁₋₂₀ alkyl group.

Substituents of Ar¹ may be provided on carbon atoms adjacent to bonds between Ar¹ groups and/or adjacent to a bond from the group of formula (II) to a ligand of formula (I). Such substituents may create a twist between Ar¹ groups of formula (II), or between a ligand and an Ar¹ group bound to the ligand, and limit conjugation therebetween.

Exemplary groups of formula (II) are illustrated below:

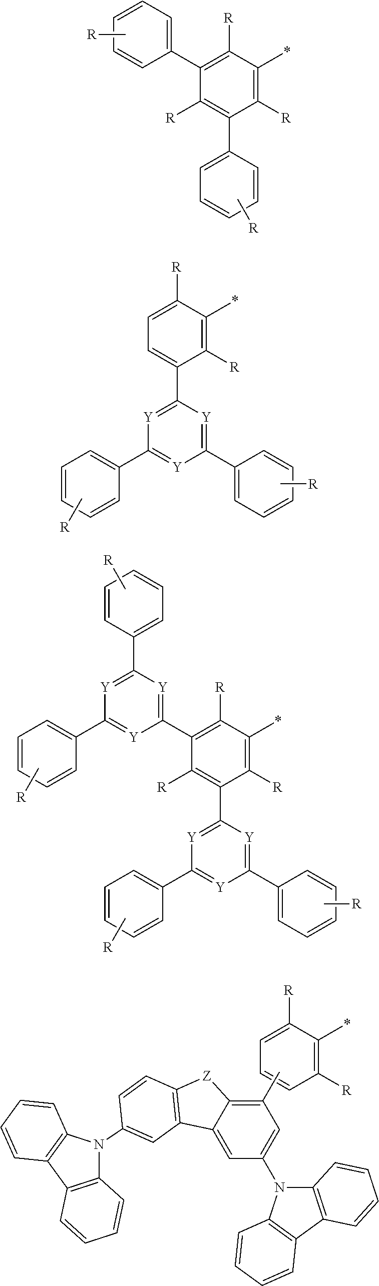

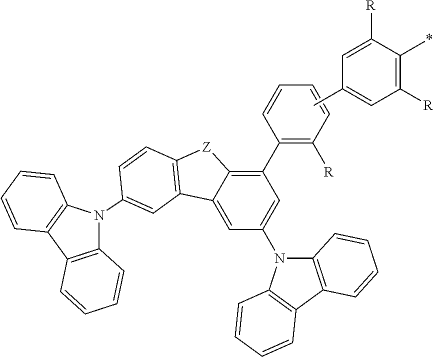

wherein R in each occurrence is H or a substituent, preferably H or a C₁₋₂₀ alkyl group.

In another preferred embodiment, X is a group of formula (III):

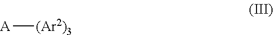

wherein A is B or N and Ar² in each occurrence is independently an aryl or heteroaryl group that may be unsubstituted or substituted with one or more substituents.

Ar² is preferably a C₆₋₂₀ aryl group, more preferably phenyl that may be unsubstituted or substituted with one or more substituents. Optionally, substituents of Ar², where present, may be selected from C₁₋₂₀ alkyl wherein one or more non-adjacent C atoms may be replaced with O, S, C═O or —COO—, and one or more H atoms may be replaced with F.

Optionally, the group of formula (III) has formula (IIIa):

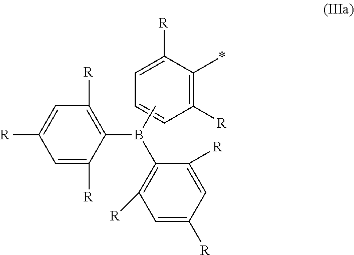

wherein R is as described above.

M may be selected from d-block metal cations of rows 2 and 3 i.e. elements 39 to 48 and 72 to 80, and is preferably a cation of ruthenium, rhodium, palladium, rhenium, osmium, iridium, platinum and gold. Preferably, M is Ir³⁺.

Optionally, x is 2 or 3. Optionally, y is 0.

Where present, L may be selected from any ligand other than ligands of formula:

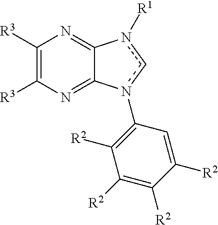

Preferably, L is a bidentate ligand.

Exemplary ligands L include diketonate ligands, for example acac, and C,N-cyclometallating ligands, optionally ligands of formula (II):

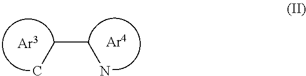

wherein Ar³ is an aryl or heteroaryl group, preferably phenyl or pyridine; Ar⁴ is a heteroaryl group, preferably a 5 or 6 membered heteroaryl group having C and N aromatic atoms, optionally imidazole, triazole or pyridine; and Ar³ and Ar⁴ may be linked to form a ring. Ar³ and Ar⁴ may be linked to form a phenanthridine ring. Ar³, Ar⁴, and any ring formed by linkage of Ar³ and Ar⁴, may each independently be unsubstituted or substituted with one or more substituents. Substituents may independently in each occurrence be selected from the group consisting of alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F; aryl and heteroaryl groups that may be unsubstituted or substituted with one or more substituents; and a branched or linear chain of aryl or heteroaryl groups. Exemplary aryl or heteroaryl groups are unsubstituted phenyl and phenyl substituted with one or more C₁₋₂₀ alkyl groups; F; CN and NO₂.

In one preferred embodiment, y is 0 in which case x is preferably 2 or 3.

In another case, x is 1 or 2 and y is 1 or 2.

Exemplary compounds of formula (I) include the following:

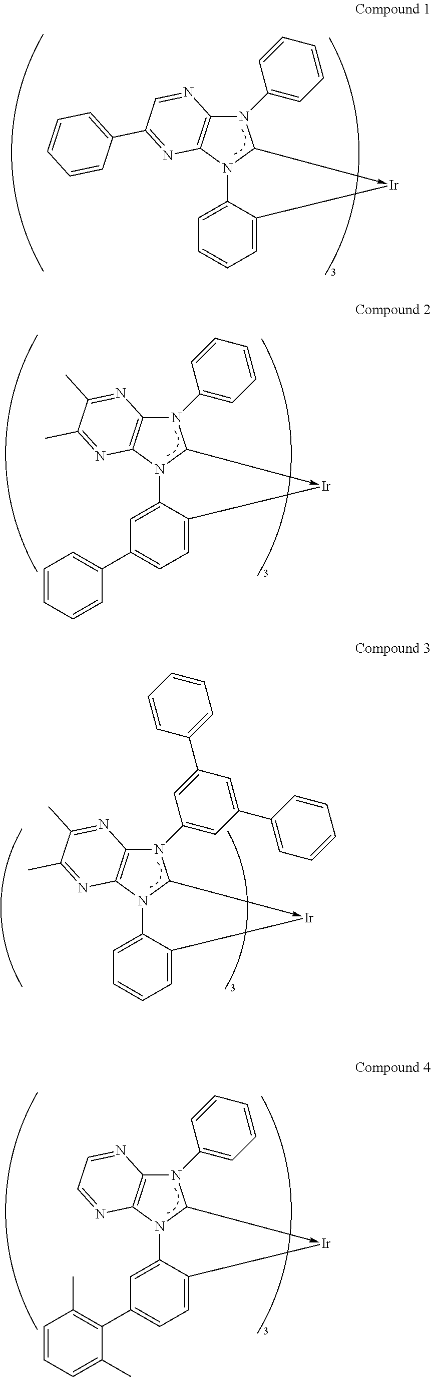

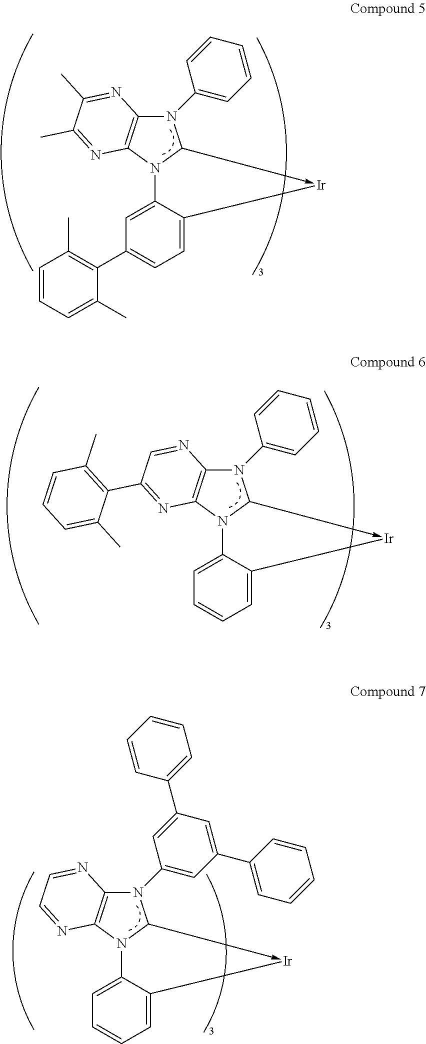

Host Materials

The light-emitting layer 103 preferably contains the compound of formula (I) and a host material. The host material may be a non-polymeric or polymeric material. The host material preferably has a lowest excited state triplet energy level that is the same as or higher than the triplet energy level of the compound of formula (I).

Exemplary non-polymeric hosts have formula (XV):

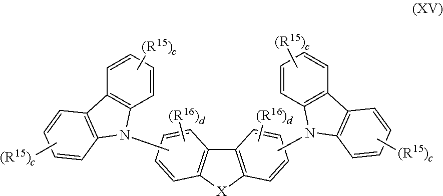

wherein each R¹⁵ and R¹⁶ is independently a substituent; X is O or S; each c is independently 0, 1, 2, 3 or 4; and each d is independently 0, 1, 2 or 3.

The host of formula (XV) may have formula (XVa):

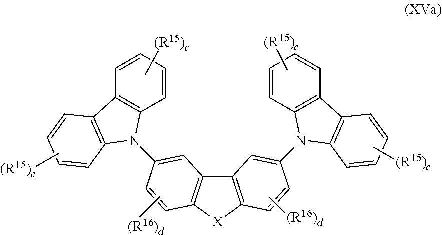

Each R¹⁵ and R¹⁶, where present, may independently in each occurrence be selected from the group consisting of alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F; aryl and heteroaryl groups that may be unsubstituted or substituted with one or more substituents; and a branched or linear chain of aryl or heteroaryl groups. Exemplary aryl or heteroaryl groups are unsubstituted phenyl and phenyl substituted with one or more C₁₋₂₀ alkyl groups; F; CN and NO₂.

X is preferably S.

Host polymers include polymers having a non-conjugated backbone with charge-transporting groups pendant from the polymer backbone, and polymers having a conjugated backbone in which adjacent repeat units of the polymer backbone are conjugated together. A conjugated host polymer may comprise, without limitation, repeat units selected from optionally substituted arylene or heteroarylene repeat units.

Exemplary arylene repeat units include, without limitation, fluorene, phenylene, phenanthrene naphthalene and anthracene repeat units, each of which may independently be unsubstituted or substituted with one or more substituents, optionally one or more C₁₋₄₀ hydrocarbyl substituents.

The host polymer may contain triazine-containing repeat units. Exemplary triazine-containing repeat units have formula (IV):

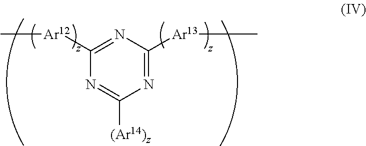

wherein Ar¹², Ar¹³ and Ar¹⁴ are independently selected from substituted or unsubstituted aryl or heteroaryl, and z in each occurrence is independently at least 1, optionally 1, 2 or 3, preferably 1.

Polymers comprising repeat units of formula (IV) may be copolymers comprising repeat units of formula (IV) and one or more co-repeat units, and may comprise repeat units of formula (IV) and one or more arylene repeat units as described above.

Any of Ar¹², Ar¹³ and Ar¹⁴ may be substituted with one or more substituents. Exemplary substituents are substituents R¹⁰, wherein each R¹⁰ may independently be selected from the group consisting of:
substituted or unsubstituted alkyl, optionally C₁₋₂₀ alkyl, wherein one or more non-adjacent C atoms may be replaced with optionally substituted aryl or heteroaryl, O, S, substituted N, C═O or —COO— and one or more H atoms may be replaced with F; and
a crosslinkable group attached directly to Ar¹², Ar¹³ and Ar¹⁴ or spaced apart therefrom by a spacer group, for example a group comprising a double bond such and a vinyl or acrylate group, or a benzocyclobutane group.

Substituted N, where present, may be —NR¹⁷— wherein R¹⁷ is a substituent, optionally a C₁₋₂₀ hydrocarbyl group.

Preferably, Ar¹², Ar¹³ and Ar¹⁴ of formula (IV) are each phenyl, each phenyl independently being unsubstituted or substituted with one or more C₁₋₂₀ alkyl groups.

Ar¹⁴ of formula (IV) is preferably phenyl, and is optionally substituted with one or more C₁₋₂₀ alkyl groups or a crosslinkable unit.

A particularly preferred repeat unit of formula (IV) has formula (IVa).

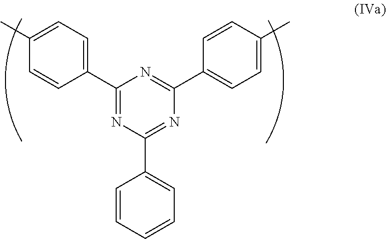

The phenyl groups of the repeat unit of formula (IVa) may each independently be unsubstituted or substituted with one or more substituents R¹⁰ as described above with respect to formula (IV), preferably one or more C₁₋₂₀ alkyl groups.

The compound of formula (I) and/or any other phosphorescent material of light-emitting layer 105, may be blended with or covalently bound to a host polymer.

A phosphorescent material may be covalently bound to a host polymer as a repeat unit in the polymer backbone, as an end-group of the polymer, or as a side-chain of the polymer. If the phosphorescent material is provided in a side-chain then it may be directly bound to a repeat unit in the backbone of the polymer or it may be spaced apart from the polymer backbone by a spacer group. Exemplary spacer groups include C₁₋₂₀ alkyl and aryl-C₁₋₂₀ alkyl, for example phenyl-C₁₋₂₀ alkyl. One or more carbon atoms of an alkyl group of a spacer group may be replaced with O, S, C═O or COO.

The compound of formula (I) mixed with a host material may form 0.1-50 weight %, optionally 0.1-30 wt % of the weight of the components of the layer containing the phosphorescent material.

If the compound of formula (I) is covalently bound to a host polymer then repeat units comprising the phosphorescent material, or an end unit comprising the phosphorescent material, may form 0.1-20 mol of the polymer.

If two or more phosphorescent materials are provided in light-emitting layer 105 then the phosphorescent material with the highest triplet energy level is preferably provided in a larger weight percentage than the lower triplet energy level material or materials.

Further Light-Emitting Compounds

Light-emitting layer 103 contains a compound of formula (I). Further light-emitting materials, if present in the light-emitting layer 103 or in another layer of the device, may each independently be selected from fluorescent or phosphorescent materials.

Phosphorescent light-emitting materials are preferably phosphorescent transition metal complexes.

Further phosphorescent light-emitting materials may be green or red-emitting phosphorescent transition metal complexes of (IX):

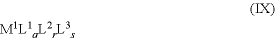

wherein M¹ is a metal; each of L¹, L² and L³ is a coordinating group; q is a positive integer; r and s are each independently 0 or a positive integer; and the sum of (a. q)+(b. r)+(c.s) is equal to the number of coordination sites available on M¹, wherein a is the number of coordination sites on L¹, b is the number of coordination sites on L² and c is the number of coordination sites on L³. Preferably, a, b and c are each 1 or 2, more preferably 2 (bidentate ligand). In preferred embodiments, q is 2, r is 0 or 1 and s is 0, or q is 3 and r and s are each 0.

Suitable metals M¹ include d-block metals, in particular those in rows 2 and 3 i.e. elements 39 to 48 and 72 to 80, in particular ruthenium, rhodium, palladium, rhenium, osmium, iridium, platinum and gold. Iridium is particularly preferred.

Exemplary ligands L¹, L² and L³ include carbon or nitrogen donors such as porphyrin or bidentate ligands of formula (X):

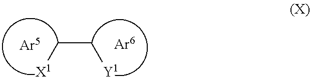

wherein Ar⁵ and Ar⁶ may be the same or different and are independently selected from substituted or unsubstituted aryl or heteroaryl; X¹ and Y¹ may be the same or different and are independently selected from carbon or nitrogen; and Ar⁵ and Ar⁶ may be fused together. Ligands wherein X¹ is carbon and Y¹ is nitrogen are preferred, in particular ligands in which Ar⁵ is a single ring or fused heteroaromatic of N and C atoms only, for example pyridyl or isoquinoline, and Ar⁶ is a single ring or fused aromatic, for example phenyl or naphthyl.

To achieve red emission, Ar⁵ may be selected from phenyl, fluorene, naphthyl and Ar⁶ are selected from quinoline, isoquinoline, thiophene and benzothiophene.

To achieve green emission, Ar⁵ may be selected from phenyl or fluorene and Ar⁶ may be pyridine.

Exemplary ligands of formula (X) include the following:

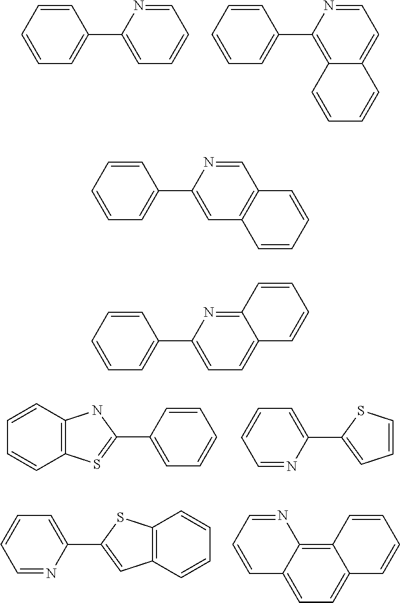

Other ligands suitable for use with d-block elements include diketonates, in particular acetylacetonate (acac), tetrakis-(pyrazol-1-yl)borate, 2-carboxypyridyl, triarylphosphines and pyridine, each of which may be substituted.

Each of Ar⁵ and Ar⁶ may carry one or more substituents. Two or more of these substituents may be linked to form a ring, for example an aromatic ring.

Exemplary substituents include groups R¹⁰ as described above with reference to Formula (IV). Particularly preferred substituents include fluorine or trifluoromethyl which may be used to blue-shift the emission of the complex, for example as disclosed in WO 02/45466, WO 02/44189, US 2002-117662 and US 2002-182441; alkyl or alkoxy groups, for example C₁₋₂₀ alkyl or alkoxy, which may be as disclosed in JP 2002-324679; charge transporting groups, for example carbazole which may be used to assist hole transport to the complex when used as an emissive material, for example as disclosed in WO 02/81448; and dendrons which may be used to obtain or enhance solution processability of the metal complex, for example as disclosed in WO 02/66552. If substituents R⁷ include a charge-transporting group then the compound of formula (IX) may be used in light-emitting layer 103 without a separate host material.

A light-emitting dendrimer comprises a light-emitting core bound to one or more dendrons, wherein each dendron comprises a branching point and two or more dendritic branches. Preferably, the dendron is at least partially conjugated, and at least one of the branching points and dendritic branches comprises an aryl or heteroaryl group, for example a phenyl group. In one arrangement, the branching point group and the branching groups are all phenyl, and each phenyl may independently be substituted with one or more substituents, for example alkyl or alkoxy.

A dendron may have optionally substituted formula (XI)

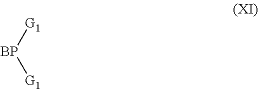

wherein BP represents a branching point for attachment to a core and G₁ represents first generation branching groups.

The dendron may be a first, second, third or higher generation dendron. G₁ may be substituted with two or more second generation branching groups G₂, and so on, as in optionally substituted formula (XIa):

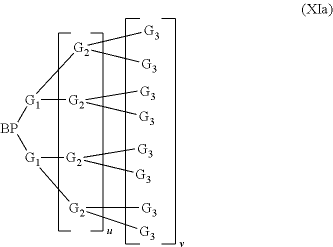

wherein u is 0 or 1; v is 0 if u is 0 or may be 0 or 1 if u is 1; BP represents a branching point for attachment to a core and G₁, G₂ and G₃ represent first, second and third generation dendron branching groups. In one preferred embodiment, each of BP and G₁, G₂ . . . Gₙ is phenyl, and each phenyl BP, G₁, G₂ . . . Gₙ₋₁ is a 3,5-linked phenyl.

In another preferred embodiment, BP is an electron-deficient heteroaryl, for example pyridine, 1,3-diazine, 1,4-diazine, 1,2,4-triazine or 1,3,5-triazine and G₂ . . . Gₙ is an aryl group, optionally phenyl.

Preferred dendrons are a substituted or unsubstituted dendron of formulae (XIb) and (XIc):

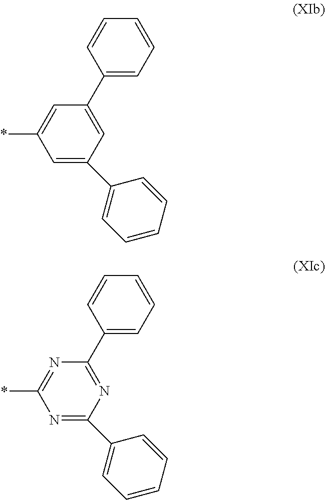

wherein * represents an attachment point of the dendron to a core.

BP and/or any group G may be substituted with one or more substituents, for example one or more C₁₋₂₀ alkyl or alkoxy groups.

Charge Transporting and Charge Blocking Layers

A hole transporting layer may be provided between the anode 101 and the light-emitting layer 103.

An electron transporting layer may be provided between the cathode 105 and the light-emitting layer 103.

A charge-transporting layer or charge-blocking layer may be cross-linked, particularly if a layer overlying that charge-transporting or charge-blocking layer is deposited from a solution. The crosslinkable group used for this crosslinking may be a crosslinkable group comprising a reactive double bond such and a vinyl or acrylate group, or a benzocyclobutane group. Crosslinking may be performed by thermal treatment, preferably at a temperature of less than about 250° C., optionally in the range of about 100-250° C.

A hole transporting layer may comprise or may consist of a hole-transporting polymer, which may be a homopolymer or copolymer comprising two or more different repeat units. The hole-transporting polymer may be conjugated or non-conjugated. Exemplary conjugated hole-transporting polymers are polymers comprising arylamine repeat units, for example as described in WO 99/54385 or WO 2005/049546 the contents of which are incorporated herein by reference. Conjugated hole-transporting copolymers comprising arylamine repeat units may have one or more co-repeat units selected from arylene repeat units, for example one or more repeat units selected from fluorene, phenylene, phenanthrene naphthalene and anthracene repeat units, each of which may independently be unsubstituted or substituted with one or more substituents, optionally one or more C₁₋₄₀ hydrocarbyl substituents.

If present, a hole transporting layer located between the anode and the light-emitting layer 103 preferably has a HOMO level of less than or equal to 5.5 eV, more preferably around 4.8-5.5 eV or 5.1-5.3 eV as measured by cyclic voltammetry. The HOMO level of the hole transport layer may be selected so as to be within 0.2 eV, optionally within 0.1 eV, of an adjacent layer (such as a light-emitting layer) in order to provide a small barrier to hole transport between these layers.

Preferably a hole-transporting layer, more preferably a crosslinked hole-transporting layer, is adjacent to the light-emitting layer containing the compound of formula (I).

A hole-transporting layer may consist essentially of a hole-transporting material or may comprise one or more further materials. A light-emitting material, optionally a phosphorescent material, may be provided in the hole-transporting layer. A light-emitting material may be blended with or covalently bound to the hole-transporting material.

A phosphorescent material may be covalently bound to a hole-transporting polymer as a repeat unit in the polymer backbone, as an end-group of the polymer, or as a side-chain of the polymer. If the phosphorescent material is provided in a side-chain then it may be directly bound to a repeat unit in the backbone of the polymer or it may be spaced apart from the polymer backbone by a spacer group. Exemplary spacer groups include C₁-₂₀ alkyl and aryl-C₁₋₂₀ alkyl, for example phenyl-C₁₋₂₀ alkyl. One or more carbon atoms of an alkyl group of a spacer group may be replaced with O, S, C═O or COO.

Covalent binding of a phosphorescent material to a hole-transporting polymer may reduce or avoid washing of the phosphorescent material out of the hole-transporting layer if an overlying layer is deposited from a formulation of the overlying layer's materials in a solvent.

The light-emitting layer 103 may be adjacent to the cathode 107. In other embodiments, an electron-transporting layer may be provided between the light-emitting layer 103 and the cathode 105.

If present, an electron transporting layer located between the light-emitting layer and cathode preferably has a LUMO level of around 1.8-2.7 eV as measured by square wave voltammetry. An electron-transporting layer may have a thickness in the range of about 5-50 nm, optionally 5-20 nm.

Electron-transporting materials for forming an electron-transporting layer may be non-polymeric or polymeric compounds and may be deposited from a solution in a solvent that the components of the light-emitting layer 103 are substantially insoluble in. The electron transporting materials may be substituted with polar groups and may be soluble in polar solvents.

Exemplary electron transporting polymers suitable for forming an electron-transporting layer are described in WO 2012/133229, the contents of which are incorporated herein by reference.

Hole Injection Layers

A conductive hole injection layer, which may be formed from a conductive organic or inorganic material, may be provided between the anode 101 and the light-emitting layer 103 of an OLED as illustrated in FIG. 1 to assist hole injection from the anode into the layer or layers of semiconducting polymer. Examples of doped organic hole injection materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion ®; polyaniline as disclosed in U.S. Pat. No. 5,723,873 and U.S. 5,798,170; and optionally substituted polythiophene or poly(thienothiophene). Examples of conductive inorganic materials include transition metal oxides such as VOx MoOx and RuOx as disclosed in Journal of Physics D: Applied Physics (1996), 29(11), 2750-2753.

Cathode

The cathode 105 is selected from materials that have a work function allowing injection of electrons into the light-emitting layer of the OLED. Other factors influence the selection of the cathode such as the possibility of adverse interactions between the cathode and the light-emitting material. The cathode may consist of a single material such as a layer of aluminium. Alternatively, it may comprise a plurality of conductive materials such as metals, for example a bilayer of a low work function material and a high work function material such as calcium and aluminium, for example as disclosed in WO 98/10621. The cathode may comprise elemental barium, for example as disclosed in WO 98/57381, Appl. Phys. Lett. 2002, 81(4), 634 and WO 02/84759. The cathode may comprise a thin (e.g. 0.5-5 nm) layer of metal compound, in particular an oxide or fluoride of an alkali or alkali earth metal, between the organic layers of the device and one or more conductive cathode layers to assist electron injection, for example lithium fluoride as disclosed in WO 00/48258; sodium fluoride; barium fluoride as disclosed in Appl. Phys. Lett. 2001, 79(5), 2001; and barium oxide. In order to provide efficient injection of electrons into the device, the cathode preferably has a workfunction of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

Encapsulation

Organic optoelectronic devices tend to be sensitive to moisture and oxygen. Accordingly, the substrate 107 preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

Formulation Processing

A formulation suitable for forming a light-emitting layer may be formed from the compound of formula (I) and a solvent. A “solvent” as described herein may be a single solvent material or a mixture of two or more solvent materials. The formulation is preferably a solution.

Solvents suitable for dissolving the compound of formula (I) include, without limitation, benzenes substituted with one or more C₁₋₁₀ alkyl or C₁₋₁₀ alkoxy groups, for example toluene, xylenes and methylanisoles, and mixtures thereof.

Particularly preferred solution deposition techniques including printing and coating techniques such spin-coating and inkjet printing.

Spin-coating is particularly suitable for devices wherein patterning of the light-emitting layer is unnecessary—for example for lighting applications or simple monochrome segmented displays.

Inkjet printing is particularly suitable for high information content displays, in particular full colour displays. A device may be inkjet printed by providing a patterned layer over the anode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, roll printing, screen printing and slot-die coating.

HOMO and LUMO Level Measurement

HOMO and LUMO levels as described anywhere herein may be measured by square wave voltammetry.

The working electrode potential may be ramped linearly versus time. When square wave voltammetry reaches a set potential the working electrode's potential ramp is inverted. This inversion can happen multiple times during a single experiment. The current at the working electrode is plotted versus the applied voltage to give the cyclic voltammogram trace.

Apparatus to measure HOMO or LUMO energy levels by CV may comprise a cell containing a tert-butyl ammonium perchlorate/or tertbutyl ammonium hexafluorophosphate solution in acetonitrile, a glassy carbon working electrode where the sample is coated as a film, a platinium counter electrode (donor or acceptor of electrons) and a reference glass electrode no leak Ag/AgCl. Ferrocene is added in the cell at the end of the experiment for calculation purposes.

Measurement of the difference of potential between Ag/AgCl/ferrocene and sample/ferrocene.

Method and settings:

3 mm diameter glassy carbon working electrode

Ag/AgCl/no leak reference electrode

Pt wire auxiliary electrode

0.1 M tetrabutylammonium hexafluorophosphate in acetonitrile

LUMO=4.8−ferrocene (peak to peak maximum average)+onset

Sample: 1 drop of 5 mg/mL in toluene spun at 3000 rpm LUMO (reduction) measurement: A good reversible reduction event is typically observed for thick films measured at 200 mV/s and a switching potential of −2.5V. The reduction events should be measured and compared over 10 cycles, usually measurements are taken on the 3^{rd} cycle. The onset is taken at the intersection of lines of best fit at the steepest part of the reduction event and the baseline. HOMO and LUMO values may be measured at ambient temperature.

### EXAMPLES

### Compound Example 1

Compound Example 1 was prepared according to Scheme 1:

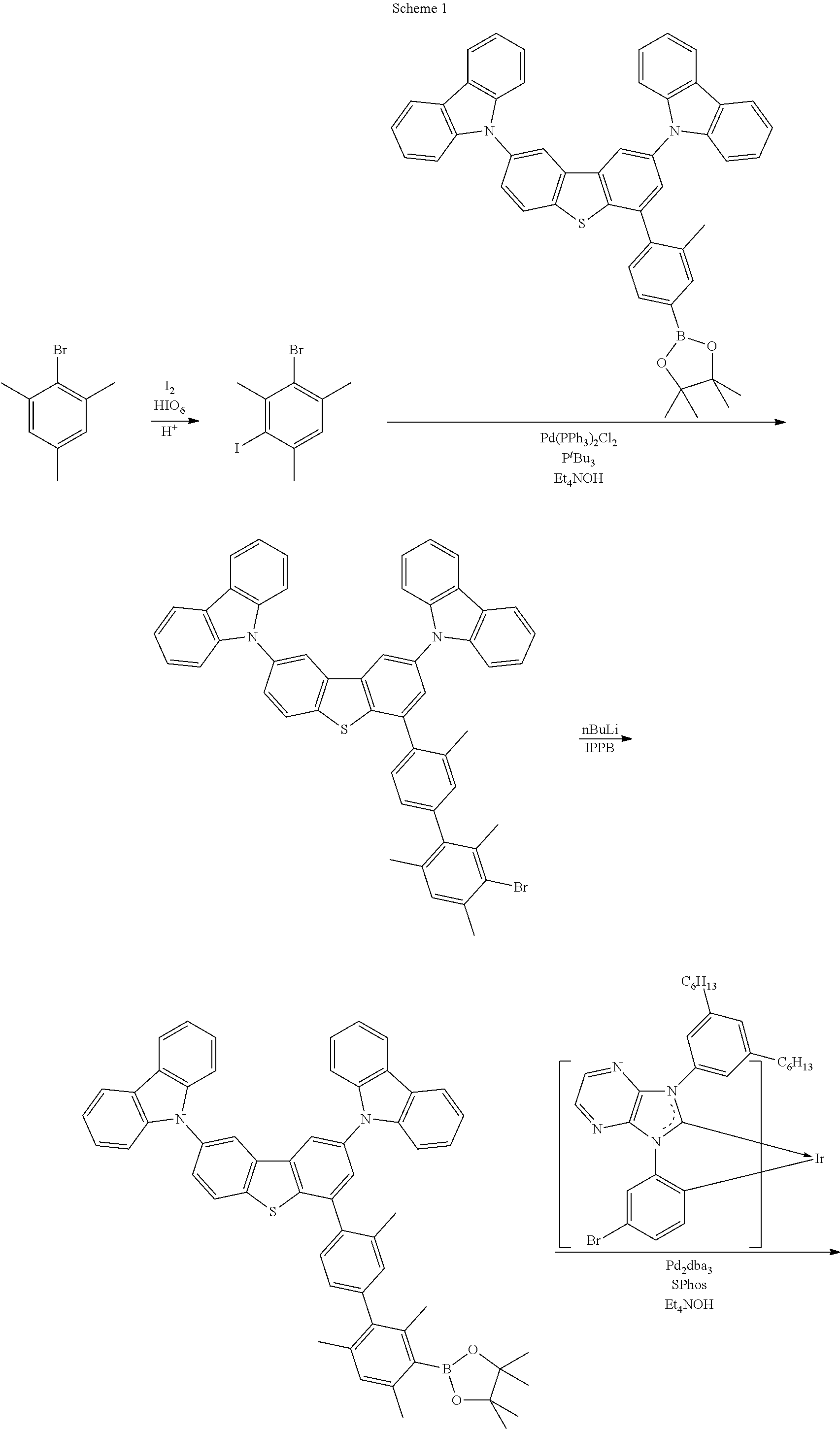

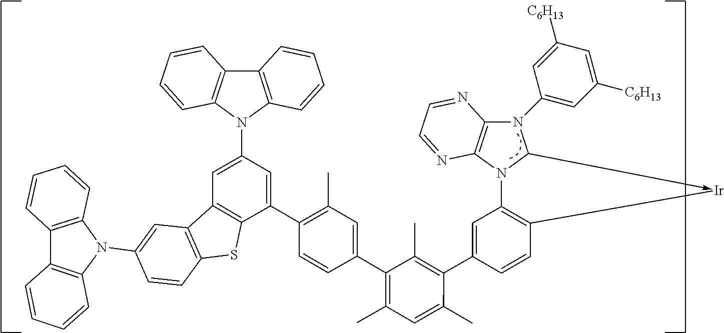

Modelling Data

The T₁-T₄ energy gap of Compound 8, illustrated below, was modelled using Gaussian09 RevC.01 as follows: geometry optimizations were performed using DFT with the B3LYP functional and basis sets LanL2DZ for iridium and 6-31G(d) for other elements. Excited state information was obtained using TD-DFT at with the same functional and basis sets.

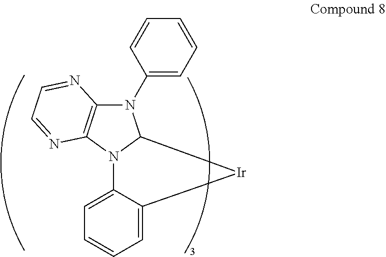

The T₁-T₄ gap is 0.32 eV.

The T₁-T₄ gap of Compounds 1-7 is at least 0.26 eV.

For comparison, the imidazopyrazine group of Compounds 1-7 was replaced with an imidazopyridyl ring. Surprisingly, the T₁-T₄ gap of imidazopyridyl analogues of Compounds 1-7 was 0.15 eV. A small T₁-T₄ may result in an undesirably long triplet excited state lifetime.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. A compound of formula (I) 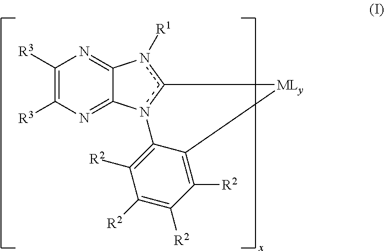
wherein:
M is a transition metal;
L is a ligand;
x is at least 1;
y is 0 or a positive integer;
R¹ in each occurrence is independently a substituent;
R² in each occurrence is independently H or a substituent; and
R³ in each occurrence is independently H or a substituent,
with the proviso that at least one of R¹, R² and R³ is a group X comprising at least one aryl or heteroaryl group.

2. A compound according to claim 1 wherein X comprises at least two aryl or heteroaryl groups.

3. A compound according to claim 1 wherein X is a group of formula (II): 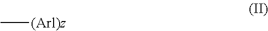
wherein Ar¹ independently in each occurrence is an aryl or heteroaryl group that may be unsubstituted or substituted; z is at least 1; and —(Ar¹)z forms a branched or linear chain of aryl or heteroaryl groups in the case where z is at least 2.

4. A compound according to claim 3 wherein X is selected from formulae (IIa)-(IIdc): 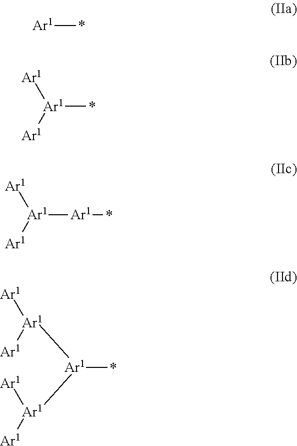
wherein * is a point of attachment to a ligand of formula (I).

5. A compound according to claim 3 wherein at least one Ar¹ comprises a substituted carbon atom adjacent to a bond between two Ar¹ groups or adjacent to a bond from the group of formula (II) to a ligand of formula (I).

6. A compound according to claim 2 wherein X is a group of formula (III): 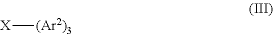
wherein X is B or N and Ar² in each occurrence is independently an aryl or heteroaryl group that may be unsubstituted or substituted with one or more substituents.

7. A compound according to claim 1 wherein X is a charge-transporting group.

8. A compound according to claim 1 wherein M is selected from the group consisting of ruthenium, rhodium, palladium, rhenium, osmium, iridium, platinum and gold.

9. A compound according to claim 1 wherein x is 2 or 3.

10. A compound according to claim 1 wherein y is 0.

11. A compound according to claim 1 wherein R¹ is a group X.

12. A compound according to claim 11 wherein at least one of R² and R³ is a group X.

13. A compound according to claim 1 wherein groups R² and R³ other than X are H.

14. A compound according to claim 1 having a photoluminescent spectrum with a peak of up to about 490 nm.

15. A composition comprising a host material and a compound according to claim 1.

16. A formulation comprising a solvent and a compound according to claim 1.

17. An organic light-emitting device comprising an anode, a cathode and a light-emitting layer between the anode and cathode wherein the light-emitting layer comprising a compound according to claim 1.

18. An organic light-emitting device according to claim 17 wherein the device is a white light-emitting device.

19. An organic light-emitting device according to claim 18 wherein the device comprises at least two light-emitting layers.

20. A method of forming an organic light-emitting device according to claim 17 comprising the steps of forming the light-emitting layer over the anode; and forming the cathode over the light-emitting layer.

21. A method according to claim 20 wherein the light-emitting layer is formed by depositing a formulation over the hole-transporting layer, and evaporating the solvent.
